(19) United States
(12) Patent Application Publication
(10) Pub. No.: US 2002/0027953 A1
(43) Pub. Date: Mar. 7, 2002

(54) Low-complexity blind equalizer

(76) Inventors: Cheng-I Hwang, Hsinchu (TW); David Wdarwei Lin, Hsinchu (TW); Sau-Gee Chen, Hsinchu (TW); Muh-Tian Shiue, Hsinchu (TW)

Correspondence Address: JACOBSON HOLMAN, PROFESSIONAL LIMITED LIABILITY COMPANY, 400 SEVENTH STREET, N.W., WASHINGTON, DC, 20004, US

(21) Appl. No.: 09/884,165

(22) Filed: Jun. 20, 2001

Related U.S. Application Data
(63) Continuation-in-part of application No. 08/869,949, filed on Jun. 5, 1997.

(51) Int. Cl. H03K 5/159

(52) U.S. Cl. 375/232; 375/348

(57) ABSTRACT

A blind equalizer structure is devised which employs an efficient filter structure for the convolution operation therein. Associated with this filter structure, two equalizer coefficient estimation (i.e., coefficient adaptation) techniques are also devised, one of which is the basic technique and the other is a reduced-complexity version of the basic technique referred to as the sign technique. The efficient filter structure reduces the amount of multiplications needed for convolution by about a half at the expense of about the same amount of increase in needed additions. Because in digital circuit implementation, multiplications are much more complicated than additions, especially when such operations are carried out on complex entities, the proposed equalizer structure can reduce the complexity of the convolution operation therein by approximately a half, thereby reducing significantly the complexity of the complete equalizer and consequently the complexity of the receiver in a digital transmission system.

This is a Continuation-In-Part of application Ser. No. 08/869,949, filed Jun. 5, 1997.

### BACKGROUND OF THE INVENTION

1. Field of the Invention

This invention relates to a technique of blind equalization for digital communication.

2. Description of the Prior Art

Intersymbol interference (ISI) is a frequently encountered problem in digital transmission. A common method for dealing with ISI is to employ an adaptive equalizer in the receiver. The equalizer has to derive proper settings of its coefficients from the received signal. Conventionally, such derivation is facilitated by having the transmitter sending out a data sequence known to the receiver. This data sequence is commonly referred to as the training sequence. The equalizer then derives its coefficient settings using the received signal as well as its knowledge of the training sequence. In contrast, several methods for adaptive equalization without using a training sequence have also been invented. These methods are commonly referred to as blind equalization methods and form a less conventional class of equalization techniques. A better known technique in the realm of blind equalization is the Godard p=2 method designed by D. N Godard and published in “Self-Recovering Equalization and Carrier Tracking in Two-Dimensional Data Communication System,” IEEE Transactions on Communications, Vol. 28, No. 11, pp. 1867-1875, November 1980. The absence of need for training sequences is of significance, for example, for systems that desire to increase the efficiency in channel usage by eliminating or at least minimizing the use of training sequences, and for systems that do not always transmit training sequences.

Structurally, both the conventional and the blind equalizers can be partitioned into two parts: a convolver part and a coefficient estimator part, of which the former performs the convolution operation of the equalizer input with the equalizer coefficients to yield the equalizer output and the latter estimates the equalizer coefficients. The latter is usually done in a recursive manner in that each equalizer coefficient is adjusted in a certain way, whose details are different from one adaptive equalization method to another, for each new input signal sample to the equalizer. Let N denote the number of equalizer coefficients. Then the convolver part requires on the order of N multiplications and N additions. The complexity of the coefficient estimator part of common adaptive equalization methods is on the order of pN multiplications and N additions, where p is a number between 0 and 1 (inclusive). Therefore, the convolver part constitutes a major portion of the overall equalizer complexity.

In “A New Efficient LMS Adaptive Filtering Algorithm,” IEEE Transactions on Circuits and Systems-II: Analog and Digital Signal Processing, Vol. 43, No. 5, pp. 372-378, May 1996, S. -G. Chen, Y. -A. Kao, and K. -Y. Tsai presented a method to implement the convolver which can reduce its complexity significantly. In essence, this is achieved by expressing the convolution operation in an unconventional but mathematically equivalent way to the conventional expression. This new way of expression only requires on the order of N/2 multiplications but on the order of 3N/2 additions, in comparison to N multiplications and N additions of the conventional expression. Since, in digital circuitry, a multiplier can be much more complicated than an adder, the new way is beneficial for implementation, especially when dealing with complex signals where a complex multiplication translates into four real multiplications and two real additions. For convenience in subsequent reference, the new way of performing convolution will be termed the decomposition technique. Chen, Kao, and Tsai also designed a training-sequence-based adaptive filtering method incorporating the decomposition technique for convolution. Their computer simulation results show comparable performance between the new adaptive filtering method and a well-known training-sequence-based adaptive filtering method. However, due to the difference in the operating principles of blind equalization and training-sequence-based adaptive filtering, Chen et al's. technique cannot be applied to blind equalization directly.

A common prior art structure employed in blind equalizers is as shown in FIGS. 1a-1d. The structure is referred to as the Godard p=2 technique and was designed by D. N. Godard and published in “Self-Recovering Equalization and Carrier Tracking in Two-Dimensional Data Communication System,” IEEE Transactions on Communications, Vol. 28, No. 11, pp. 1867-1875, November 1980. As is the case with all adaptive equalizers and adaptive filters, the above blind equalizer structure can be distinguished into two parts. With reference to FIG. 1a, one part is the convolver which is composed of the elements outside the C-shaped box outlined with dashed line (106), but including the signal lines that pass directly through it (107₀, 107₁, . . . , 107_{N-1}). Plotted alone, the convolver part has the structure shown in FIG. 1b, where for clarity the signal lines in FIG. 1a that end in the C-shaped box (i.e., 108₀, 108₁, 108_{N-1}, and 109) are omitted from the diagram in FIG. 1b. The other part is the coefficient estimator which is composed of the elements inside the C-shaped box in FIG. 1a that is outlined with dashed line (106), but excluding the signal lines that pass directly through it (107₀, 107₁, . . . , 107_{N-1}). In the figures, N is a design parameter to be chosen according to the operating environment.

With reference to FIG. 1b, the function of the convolver is to calculate the mathematical entity

$$z ( n ) = {\sum }_{k = 0}^{N - 1} {C}_{k} ( n ) \times ( n - k )$$

at each time n, where Cₖ(n) denotes the equalizer coefficient corresponding to the k-sample delayed input at time n, as one skilled in the art of digital communication transmission engineering well knows. The calculation is accomplished by feeding the sequence of equalizer input signal samples x(n) through the series of delay elements (100₀, 100₁, 100_{N-1}), each of which providing a unit-sample delay, multiplying each of the delayed signal samples with the corresponding equalizer coefficient Cₖ(n) (as indicated by the elements 102₀, 102₁, . . . , 102_{N-1}), and summing the products together (as indicated by the element 103). The quantity z(n) constitutes the equalizer output at time n.

The coefficient estimator 106 estimates the inverse of the impulse response of the communication channel. The estimation in most cases is approximate and its accuracy depends on the operating environment and the chosen design parameters (including the aforementioned N and the adaptation step size parameter to be described below) and is therefore subject to the discretion of the implementer in each situation. As shown in FIG. 1a, the coefficient estimator 106 is composed of a number of components including N coefficient adapters (101₀, 101₁, . . . , 101_{N-1}), a blind error calculator (104), an error scaler (105), and the associated signal lines. Mathematically, the function of the coefficient estimator part is to perform the following computation:

Ck(n+1)=Ck(n)−s er(n)x*(n−k)

for all k=0,1, . . . ,N−1, where

er(n)=z(n)(|z(n)|²2−R),

the superscript “*” denotes complex conjugation, and R is a number explained hereinafter.

In the coefficient estimator, the coefficient adapters have the same structure and one of them (101ₖ where k may be any number between 0 and N−1 inclusive) is illustrated in FIG. 1c. It takes x(n−k), which is the k-th delayed sample of the equalizer input, as one input and feeds the sample through a conjugator (200) to obtain its complex conjugate. The conjugator output and ser(n), which is the output of the error scaler (105), are then multiplied together (201). The product is fed into a subtraction operation (202) to adjust the k-th equalizer coefficient Cₖ(n). After a unit-sample delay (203), the adjusted coefficient will become the k-th equalizer coefficient at the next time instant. The blind error calculator has the structure shown in FIG. 1d. It takes z(n), the output of the convolver at time n, as the input and feeds it through the squared-magnitude calculator (204). A number R is subtracted (205) from the squared magnitude of z(n), where R is the ratio of the expected value of the fourth-power values of the magnitudes of the transmitted data symbols from the remote end to the expected value of the squared magnitudes of the transmitted data symbols from the remote end. The difference is multiplied (206) with z(n) to form the blind error signal er(n), which is the output of the blind error calculator (104). The scaler (105) multiplies er(n) with a adaptation step size s (which is a design parameter to be chosen be at the discretion of the implementer and which may vary with time) to result in the signal ser(n), which constitutes one of the two inputs to each coefficient adapter (101ₖ).

With properly chosen design parameters N and s, the intersymbol interference (ISI) present in the equalizer output z(n) can be made smaller than that present in its input x(n), thus attaining the purpose of equalization. In a practical communications receiver, the signal z(n) may be fed into a simple decision circuit to determine what the transmitted data from the remote end are, or into a more involved structure (such as a decision-feedback equalizer or a maximum-likelihood sequence estimator) for a more accurate determination.

The essence of the above design is that it requires no knowledge of the transmitted data symbols from the remote end, but only a statistic denoted R as shown in FIG. 1d and as explained above. In contrast, conventional adaptive equalizers require knowledge of the remote-transmitted data symbols for coefficient adaptation. Therefore, a training sequence, or multiple instances of training sequences, is inserted into the transmitted data stream to facilitate such adaptation. The absence of need for training sequences is of significance, for example, for systems that want to increase the efficiency in channel usage by eliminating or at least minimizing the use of training sequences, and for systems that do not always transmit training sequences.

In digital circuits, the multiplier is a highly complex structure. In the coefficient estimator part of an adaptive equalizer, the need for a multiplier is often bypassed in a coefficient adapter (101ₖ) by employing a so-called sign algorithm wherein either er(n) is hardlimited to ±1 prior to scaling (105) or the output of the conjugator (200) is hardlimited to ±1 prior to performing the multiplication operation (201) or both. If er(n) is hardlimited prior to scaling, then the most appropriate value for the number R in the blind error calculator (104) may not be the ratio of two expected values as described previously, but some other value. Experiments in the form of computer simulation can be conducted to find a value which results in low ISI in the equalizer output z(n). Also for complexity reason, the adaptation step size s is often chosen to be an integral power of 2 to facilitate multiplierless operation of the scaler (105), or chosen to be a simple binary number to facilitate a simple multiplication operation. Under this circumstance, the convolver part becomes the place where much of the equalizer complexity resides.

S. -G. Chen, Y. -A. Kao, and K. -Y. Tsai presented a training-sequence-based adaptive filtering method in “A New Efficient LMS Adaptive Filtering Algorithm,” IEEE Transactions on Circuits and Systems-II: Analog and Digital Signal Processing, Vol. 43, No. 5, pp. 372-378, May 1996. This method is based on the aforementioned decomposition technique to implement the convolver which can reduce its complexity significantly compared to the customary way of implementation.

FIGS. 2a-2e illustrate the structure of the proposed adaptive filter for the case where the number of equalizer coefficients N in the convolver part is even. The case where N is odd is a simple modification of the present case and will be described later.

With reference to FIG. 2a, the convolver part is composed of the elements outside the C-shaped box outlined with dashed line (306), but including the summers 310₀, 310₁, . . . , and 310_{N-1} together with their input signal lines 307₀, 307₁, 307_{N-1}, 311₀, 311₁, . . . , and 311_{N-1} and their output signal lines 312₀, 312₁, . . . , and 312_{N-1}. The coefficient estimator part is composed of the elements inside the C-shaped box 306 but excluding the summers and their input and output signal lines as described above.

Plotted alone, the convolver part, implementing the decomposition technique, has the structure shown in FIG. 2b. It calculates the following mathematical entity

$$z ( n ) = {\sum }_{k = 0}^{N / 2 - 1} [ x ( n - 2 k ) + {C}_{2 k + 1} ( n ) ] [ x ( n - 2 k - 1 ) + {C}_{2 k} ( n ) ] - g ( n ) - k ( n )$$

where g(n) is the output of the input-effect calculator 313 and h(n) is the output of the coefficient-effect estimator 317 in FIG. 2a. The quantity z(n) constitutes the equalizer output at time n. If

$$g ( n ) = {\sum }_{k = 0}^{N / 2 - 1} \times ( n - 2 k ) \times ( n - 2 k - 1 )$$

$$and$$

$$h ( n ) = {\sum }_{k = 0}^{N / 2 - 1} {C}_{2 k} ( n ) {C}_{2 k + 1} ( n ) ,$$

then it can be easily shown by one skilled in the art of digital communication transmission engineering that the convolver of FIG. 2b executes a mathematically equivalent function as the convolver of FIG. 1b. Excluding the computation needed to obtain g(n) and h(n), the above expression for z(n) requires only N/2 multiplications but 3N/2+1 additions (subtractions included). Since, in digital circuitry, multiplications are much more complicated than additions, especially when the entities involved are complex numbers, the above way of calculating z(n) is more advantageous than the customary way embodied in FIG. 1b, which requires N multiplications and N−1 additions, provided that the computation of g(n) and h(n) does not require more complexity than has been saved. Accordingly, the object of the input-effect calculator 313 is to obtain the quantity g(n) by proper means. Note that the expression for g(n) can be manipulated mathematically into the following form:

g(n)=g(n−2)−x(n−N)x(n−N−1)+x(n)x(n−1).

Two possible embodiments of the calculator for g(n) are shown in FIGS. 2c and 2d, respectively. The primary difference between the two embodiments is that the one of FIG. 2c employs a multiplier to calculate x(n−N)x(n−N−1) at time n while that of FIG. 2d employs a shift register of length N to effect the same purpose.

Concerning the quantity h(n), it has to be calculated at each time because the values of Cₖ(n) (k=0,1, . . . ,N−1) usually vary with time in an unknown manner. If it is calculated according to the mathematical expression given above, then it will cost N/2 multiplications and N/2−1 additions which will more than nullify the reduction in number of multiplications afforded by the decomposition technique for convolution. Chen et al. introduced a low-complexity technique for estimating h(n), shown as the coefficient-effect estimator 317 in FIG. 2a which will be described subsequently.

The following describes the operation of the coefficient estimator part 306 of the adaptive filter. With reference to FIG. 2a, the adaptive filter requires the presence of a desired signal d(n), generally indicated by reference numeral 316 to carry out its coefficient estimation function. In the case of equalization, during the period (or periods) when the training sequence is sent, d(n) is set equal to the known training sequence value at time n. During other times, d(n) may be set equal to the decision output of the communications receiver for time n, where the decision may be made based on the equalizer output z(n), generally referred to by numeral 309 or on further processed values from z(n). The details of how d(n) may be determined at these times are not relevant to the present invention.

Mathematically, the function of the coefficient estimator part is to perform the following computation:

Cₖ(n+1)=Cₖ(n)−s er(n)x*(n−k)

for all k=0,1, . . . ,N−1, and

h(n+1)=h(n)+u er(n),

where

er(n)=z(n)−d(n)

and the superscript “*” denotes complex conjugation. These equations were derived in accordance with the well-known LMS adaptive filtering approach (see, e.g., S. Haykin, Adaptive Filter Theory, 2nd ed., Prentice-Hall, Englewood Cliffs, N.J., 1991, ch. 9).

In the coefficient estimator, the equalizer output z(n) 309 is subtracted at 315 from d(n) generally indicated by numeral 316 to form the error signal er(n), which is multiplied with an adaptation step size s by the scaler 305 to yield ser(n). The quantity ser(n) is fed into the coefficient adapters 301₀, 301₁, . . . , 301_{N-1}, where each of the coefficient adapters 301₀, 301₁, . . . , 301_{N-1} is of the same structure as one illustrated in FIG. 1c for the Godard p=2 blind equalizer.

As in the case of blind equalization, a so-called sign algorithm may be employed for simplicity, in which either er(n) is hardlimited to +1 prior to scaling at 305 or the conjugator output in each coefficient adapter is hardlimited to prior to performing the multiplication or both. The details of the coefficient-effect estimator 317 are illustrated in FIG. 2e. It takes the error signal er(n) and passes it through the scaler 450 to scale it by the adaptation step size u. The scaled error signal is fed into a subtraction operation 451 to adjust the coefficient-effect estimate h(n). After a unit-sample delay 452, the adjusted estimate will become the estimate at the next time instant.

In FIGS. 2a-2e and the associated description as previously set forth, the number of equalizer coefficients N for the convolver part has been assumed to be even. For an odd N, let N′=N+1 and substitute all appearances of N in FIGS. 2a-2e and the associated description above by N′, then omit all the appearances of C_{N′-1} (n). In particular, the coefficient adapter 301_{N′-1} in FIG. 2a (recall that N′ has now replaced N in the figure) is omitted along with the summation 310_{N′-2}, making the signal line 312_{N′-2} directed connected with the signal line 307_{N′-2}. The result is the structure for odd N.

It is verified via computer simulation (see Chen et al., “A New Efficient LMS Adaptive Filtering Algorithm,” IEEE Transactions on Circuits and Systems-II: Analog and Digital Signal Processing, Vol. 43, No. 5, pp. 372-378, May 1996) that the coefficient-effect estimator structure embodied in FIG. 2e is able to estimate the quantity

$${\sum }_{k = 0}^{N / 2 - 1} {C}_{2 k} ( n ) {C}_{2 k + 1} ( n )$$

as desired. Similar to the case of Godard p=2 blind equalization, the number of filter coefficients N for the convolver part and the adaptation step sizes s and u are design parameters to be chosen at the discretion of the implementer. In addition, the adaptation step sizes s and u may vary with time. For complexity reason, the step sizes s and u can be chosen to be integral powers of 2 or simple binary numbers to facilitate ease of scaler implementation 305, 450. Accordingly, being a training-sequence-based adaptive filtering method, Chen et al's. technique cannot be applied to blind equalization readily.

### SUMMARY OF THE INVENTION

An object of the present invention is to devise blind equalization methods with much reduced complexity than usual methods (such as the Godard p=2 method) by employing the decomposition technique to carry out the required convolution.

A major feature of this invention is the application of an efficient filter structure to the convolver part of an blind equalizer. An associated major feature is a basic technique for coefficient estimation (also known as coefficient adaptation) for the blind equalizer employing the above efficient filter structure in its convolver part. Accordingly, the amount of multiplications needed for the convolution operation in the equalizer is reduced to about a half at the expense of about the same amount of increase in needed additions.

More precisely, the amount of multiplications is reduced from N to either [N/2]+1 or [N/2]+2 depending on the way a particular intermediate quantity in the convolution operation is calculated, while the amount of additions is increased from N−1 to N+[N/2]+2; where N denotes the number of equalizer coefficients and [A] denotes the ceiling of A (i.e., the smallest integer equal to or greater than A). Because in digital circuit implementation, multiplications are much more complicated than additions, especially so when such operations are performed on complex (i.e., non-real) entities, the proposed equalizer structure is able to reduce the complexity of the convolver to approximately a half of the customary approach, thereby reducing significantly the complexity of the complete equalizer and consequently the complexity of the receiver of a digital transmission system.

Yet another major feature of this invention is a reduced-complexity technique (in comparison to the basic technique mentioned above), called the sign technique, for equalizer coefficient adaptation. This technique eliminates the need for the ability to multiply two arbitrary numbers in the coefficient estimator part of the equalizer.

Accordingly, it is an object of the invention to provide a method of blind equalization at low complexity employing a technique, capable of reducing or removing ISI from received signals to derive correct transmitted data without needing the transmitting end of the received signal to send out training sequences. The method comprising the following steps at each sample time:

executing a convolver operation for convolution between equalizer inputs and equalizer coefficients by a decomposition technique which uses the coefficients and coefficient-effect estimate supplied by the coefficient estimator operation;

executing a coefficient estimator operation for updating of the coefficients and coefficient-effect estimate for use by the convolver operation at the next time instant, which is further comprised of the steps of:

executing a blind error calculator operation for a value based on the current-time output of the convolver operation for use in coefficients adaptation and coefficient-effect estimation;

executing an error scaler operation for the multiplication of output value of the blind error calculator operation by an adaptation step size;

executing coefficient adapters operation for adjustment of the coefficients based on current and past equalizer inputs and the output of the error scaler operation; and

executing a coefficient-effect estimator operation for adjustment of the coefficient-effect estimate by a scaled value of the output of the blind error calculator operation.

It is a further object of the invention to provide the method of blind equalization at low complexity wherein the technique is a sign technique.

A further object of the invention is to provide the method of blind equalization at low complexity wherein the error scaler operation outputs a positive or negative adaptation step size value depending on whether the output value of the blind error calculator is nonnegative or negative.

A still further object of the invention is to provide an apparatus for blind equalization at low complexity employing a technique, capable of reducing or removing ISI from the received signals to derive the correct transmitted data without needing the transmitting end to send out training sequences, the apparatus comprising:

convolver means to calculate, at each sample time, the convolution between equalizer input and the equalizer coefficients by the decomposition technique, using the coefficients and coefficient-effect estimate supplied by the coefficient estimator; and

coefficient estimator means to provide the convolver, at each sample time, with current-time coefficients and coefficient-effect estimate and to update the coefficients and coefficient-effect estimate for use by the convolver at the next time instant, which is further comprised of:

blind error calculator means which calculates a value based on the current-time output of the convolver for the use in coefficients adaptation and coefficient-effect estimation;

error scaler means which multiplies the output value of the blind error calculator by an adaptation step size;

coefficient adapters means which adjusts the coefficients based on current and past equalizer inputs and the output of the error scaler; and

coefficient-effect estimator means which adjusts the coefficient-effect estimate by a scaled value of the blind error calculator output.

Another object of the invention is to provide the apparatus for blind equalization wherein the technique is a sign technique.

An object of the invention is to provide the apparatus for blind equalization wherein the error scaler means outputs a positive or negative adaptation step size value depending on whether the output value of the blind error calculator is nonnegative or negative.

These together with other objects and advantages which will become subsequently apparent reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1a is a diagram of the prior art blind equalizer structure;

FIG. 1b is a diagram of the convolver part of the prior part blind equalizer structure;

FIG. 1c is a diagram of the coefficient adapter in the coefficient estimator part of the prior art blind equalizer structure;

FIG. 1d is a diagram of the blind error calculator in the coefficient estimator part of the prior art blind equalizer structure;

FIG. 2a is a diagram of the prior art adaptive filter based on the decomposition technique for convolution;

FIG. 2b illustrates the structure of the convolver employing the decomposition technique for the prior art adaptive filter of FIG. 2a;

FIG. 2c illustrates one way of embodying the input-effect calculator in the prior art convolver of FIG. 2b;

FIG. 2d illustrates a second way of embodying the input-effect calculator in the prior art convolver of FIG. 2b;

FIG. 2e illustrates the structure of the coefficient-effect estimator in the coefficient estimator part of the prior art adaptive filter based on the decomposition technique as shown in FIG. 2a;

FIG. 3a is the block diagram of the low-complexity blind equalizer of the present invention;

FIG. 3b illustrates the structure of the convolver part of the low-complexity blind equalizer of FIG. 3a;

FIG. 3c illustrates one way of embodying the input-effect calculator in the convolver of FIG. 3b;

FIG. 3d illustrates a second way of embodying the input-effect calculator in the convolver of FIG. 3b;

FIG. 3e is a diagram of the coefficient adapter in the coefficient estimator part of the low-complexity blind equalizer of FIG. 3a;

FIG. 3f illustrates the structure of the coefficient-effect estimator in the coefficient estimator part of the low-complexity blind equalizer of FIG. 3a;

FIG. 3g illustrates one possible way of embodying the error scaler in the coefficient estimator part of the low-complexity blind equalizer of FIG. 3a, referred to as the basic technique;

FIG. 3h illustrates a reduced-complexity way of embodying the error scaler in the coefficient estimator part of the low-complexity blind equalizer of FIG. 3a, referred to as the sign technique; and

FIG. 3i is a diagram of the blind error calculator in the coefficient estimator part of the low-complexity blind equalizer of FIG. 3a.

### DETAILED DESCRIPTION

Although only a few preferred embodiments of the invention are explained in detail, and it is to be understood that the embodiments are given by way of illustration only. It is not intended that the invention is to be limited in its scope to the details of construction and arrangement of components set forth in the following description or illustrated in the drawings. The invention is capable of other embodiments and of being practiced or carried out in various ways. Also, in describing the preferred embodiments, specific terminology will be resorted to for the sake of clarity. It is to be understood that each specific term includes all technical equivalents which operate in a similar manner to accomplish a similar purpose.

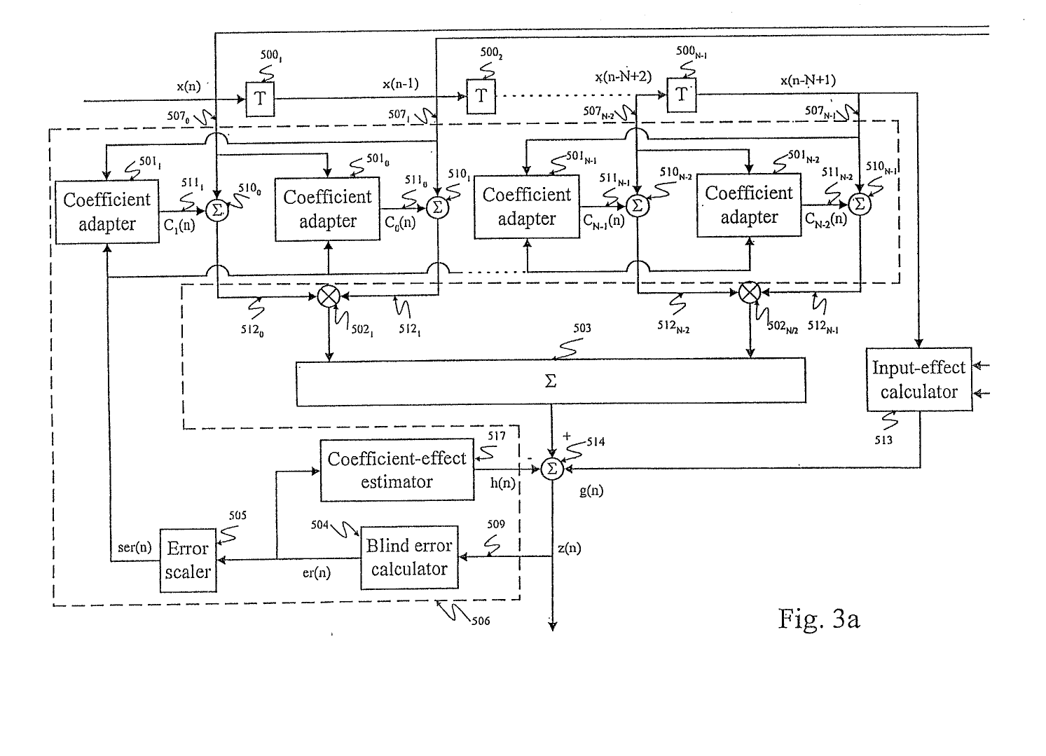

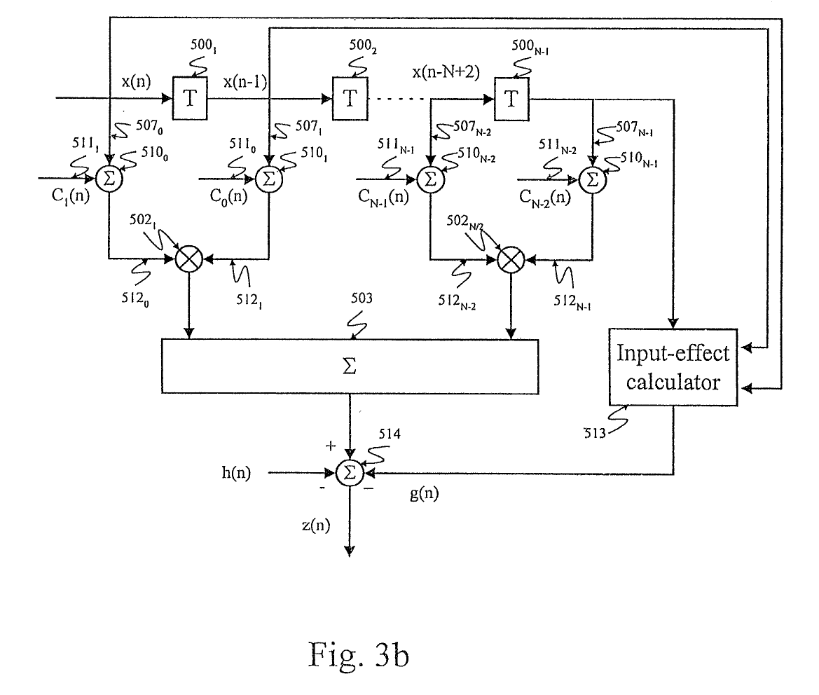

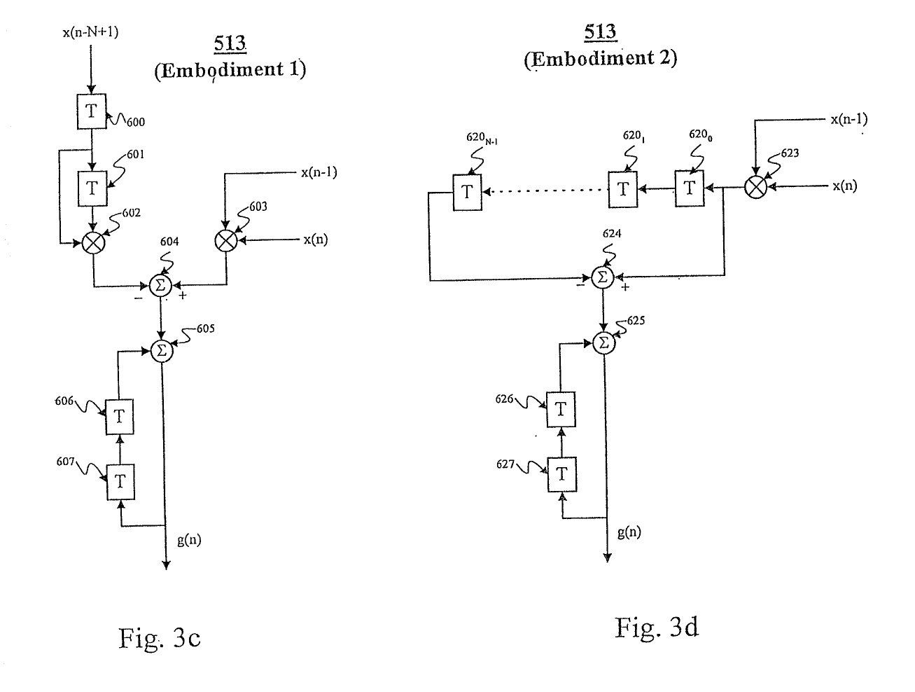

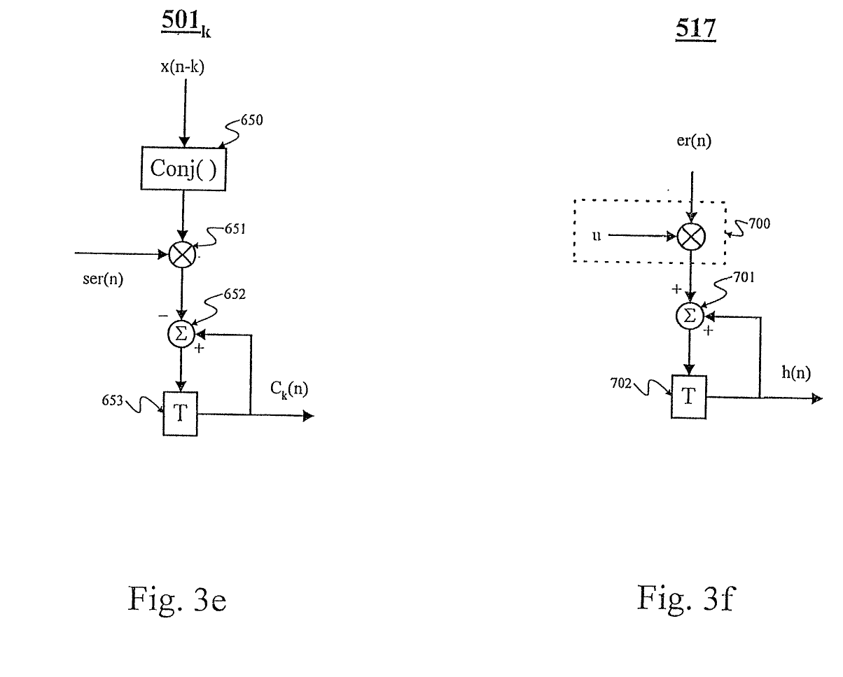

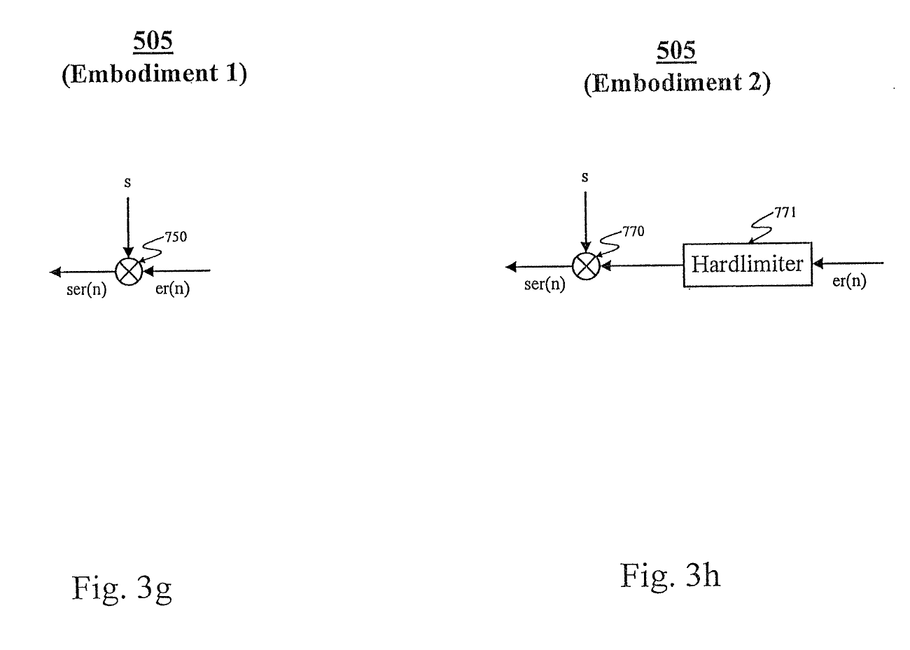

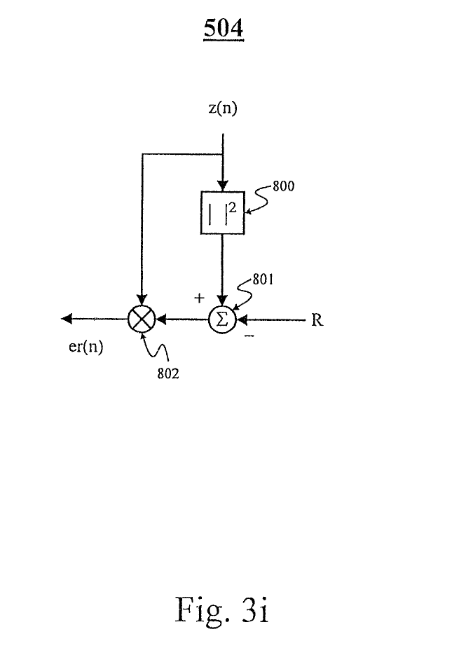

The overall structure of the blind equalizer of the present invention is shown in FIG. 3a, for the case where the number of equalizer coefficients N in the convolver part is even. The case where N is odd is a simple modification of the present case and is described later. As with other adaptive equalizers, the structure is distinguished into two parts: a convolver part and a coefficient estimator part, of which the former performs the convolution operation of the equalizer input with the equalizer coefficients to yield the equalizer output z(n) and the latter estimates the equalizer coefficients. The convolver part is composed of the elements outside the C-shaped box outlined with dashed line (506), but including the summers 510₀, 510₁, . . . , and 510ₙ₋₁ together with their input signal lines 507₀, 5071, . . . , 507_{N-1}, 511₀, 511₁, . . . , and 511ₙ₋₁ and their output signal lines 512₀, 512₁, . . . , and 512_{N-1}. The coefficient estimator part is composed of the elements inside the C-shaped box 506 but excluding the summers and their input and output signal lines as described above.

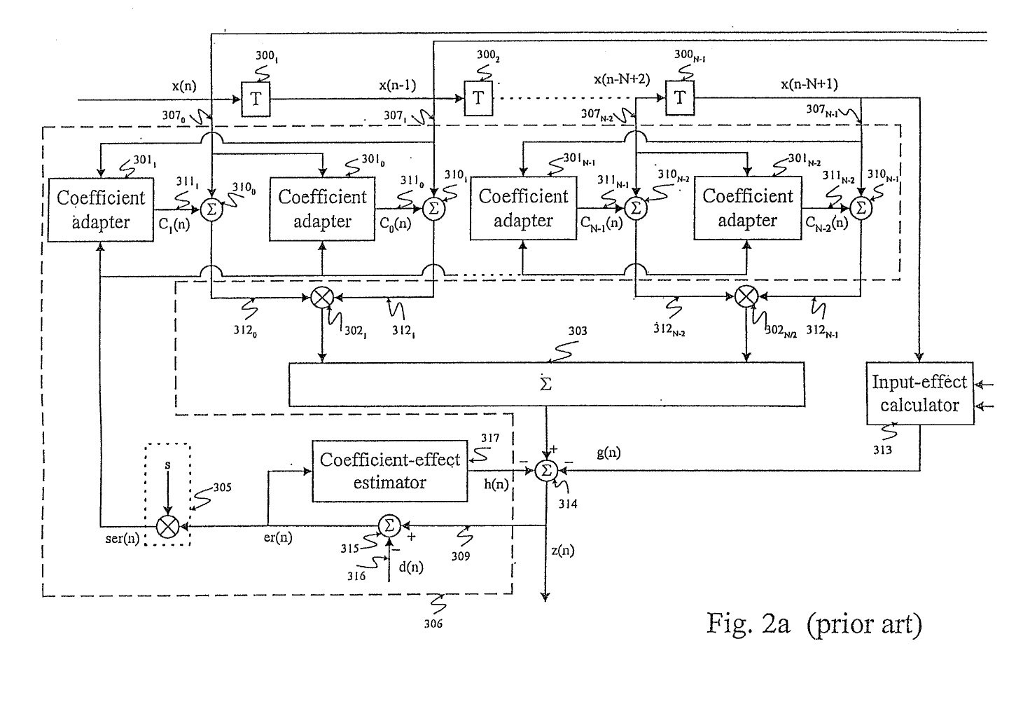

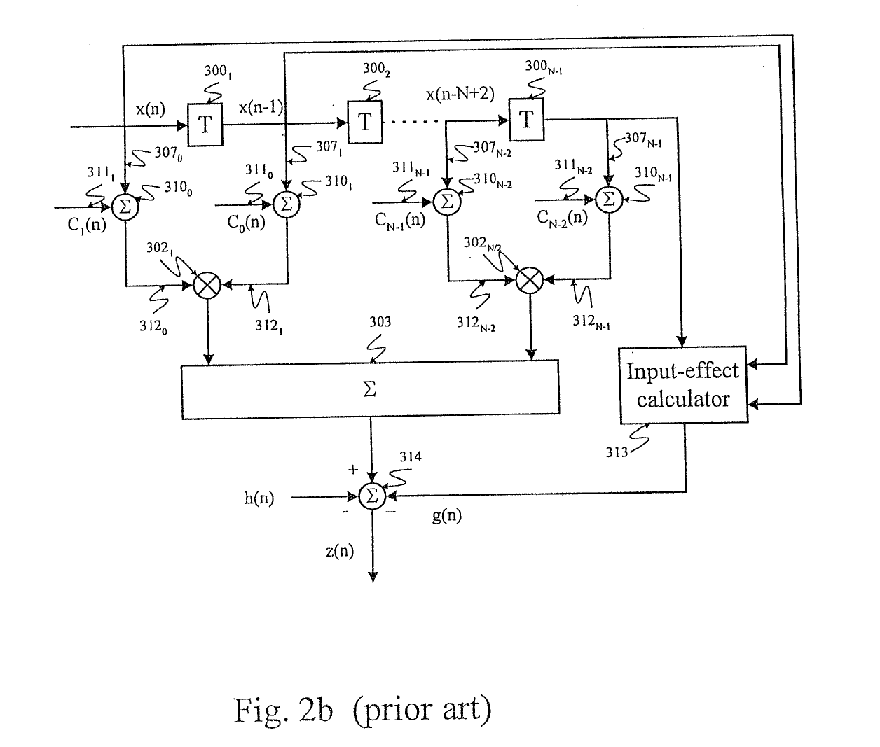

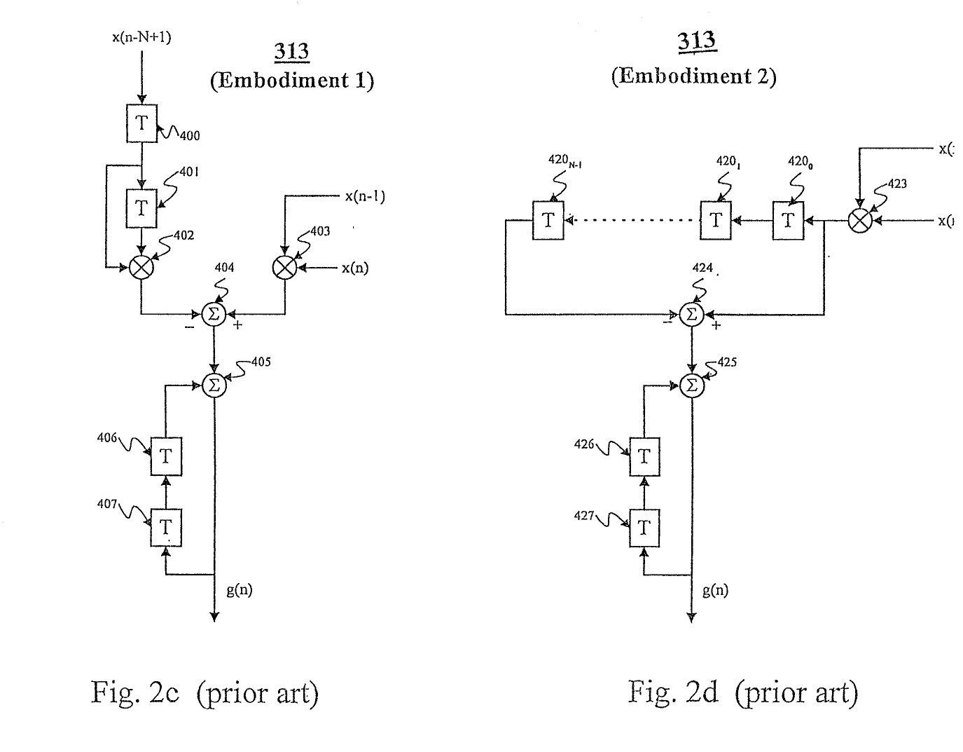

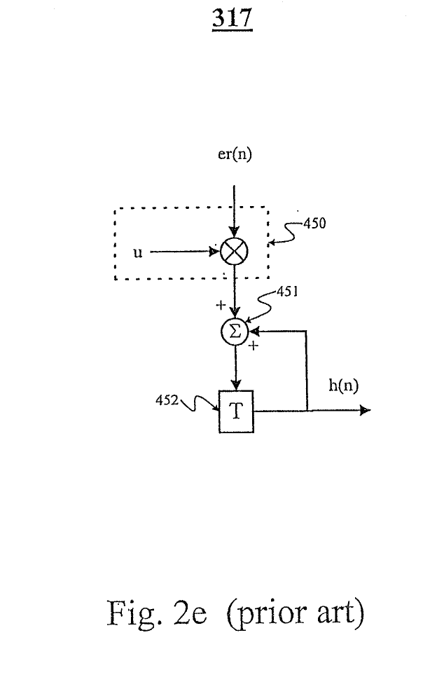

The convolver part implements the decomposition technique. When plotted alone, it has the structure shown in FIG. 3b, which is the same as FIG. 2b except for different numeral designations of the components. It calculates the mathematical entity

$$z ( n ) = {\sum }_{k = 0}^{N / 2 - 1} [ x ( n - 2 k ) + {C}_{2 k + 1} ( n ) ] [ x ( n - 2 k - 1 ) + {C}_{2 k} ( n ) ] - g ( n ) - h ( n )$$

as discussed before. As in the case of Chen et al's. adaptive filter, the input-effect calculator (513) calculates the following quantity at each time n:

g(n)=g(n−2)−x(n−N)x(n−N−1)+x(n)x(n−1).

Two possible embodiments of the calculator are shown in FIGS. 3c and 3d, respectively. They are structurally the same as FIGS. 2c and 2d, respectively, except for different numeral designations of the components.

The coefficient estimator part is composed of N coefficient adapters (501₀, 501₁, . . . , 501_{N-1}), a blind error calculator (504), an error scaler (505), a coefficient-effect estimator (517), and their input and output signal lines. Among these elements the ones accomplishing the final required coefficient estimation for the convolver part of the equalizer are the coefficient adapters (which estimates the Cₖ(n) where k=0,1, . . . ,N−1) and the coefficient-effect estimator (which estimates h(n)). The other elements, namely, the blind error calculator and the error scaler, are supportive of this estimation. Mathematically, the function of the coefficient estimator part is to perform the following computation:

Cₖ(n+1)=Cₖ(n)−s f(er(n))x*(n−k)

for all k=0,1, . . . ,N−1, and

h(n+1)=h(n)+u er(n),

where

er(n)=z(n)(|z(n)|²2−R),

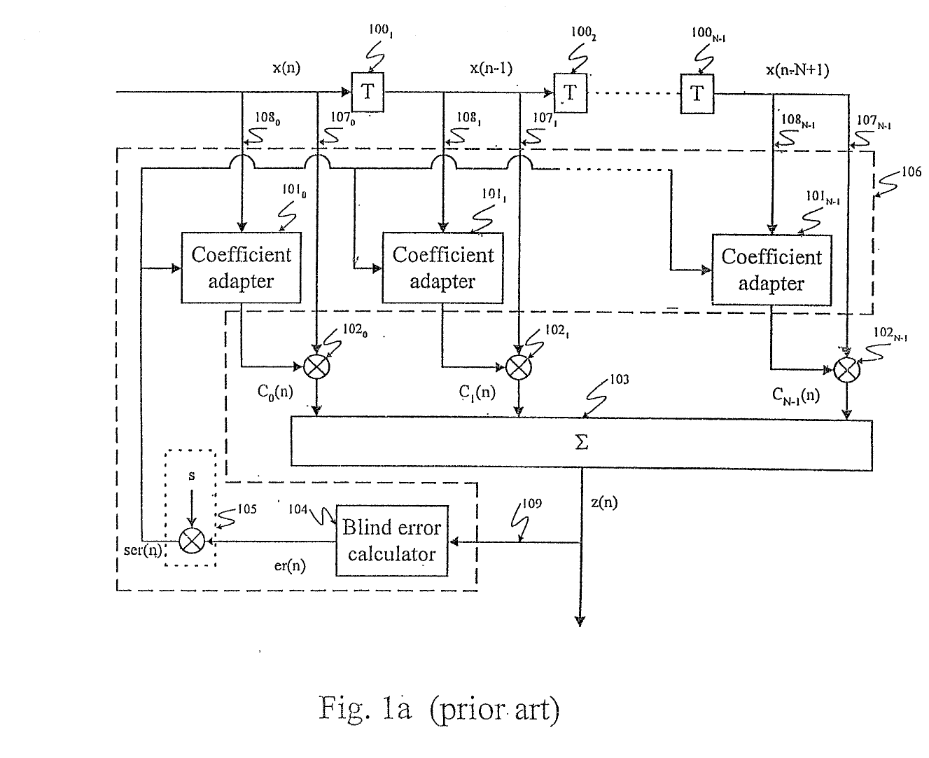

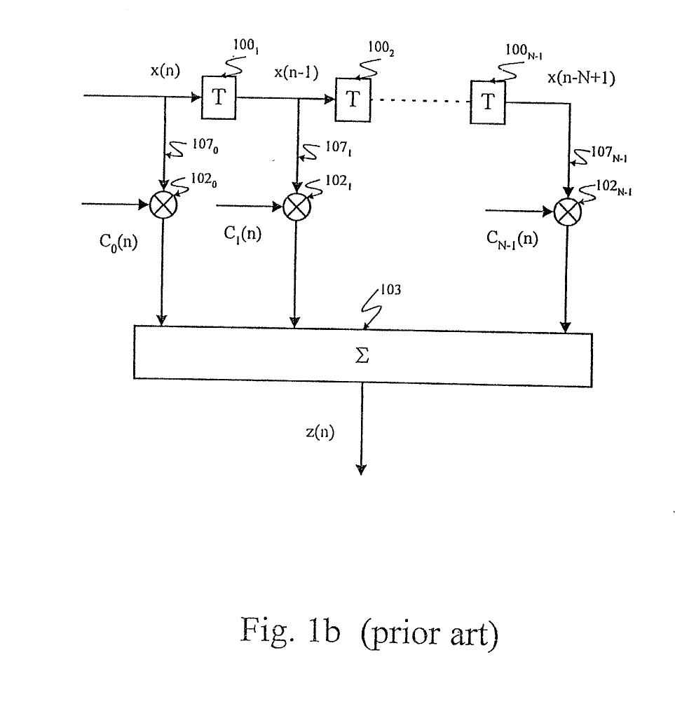

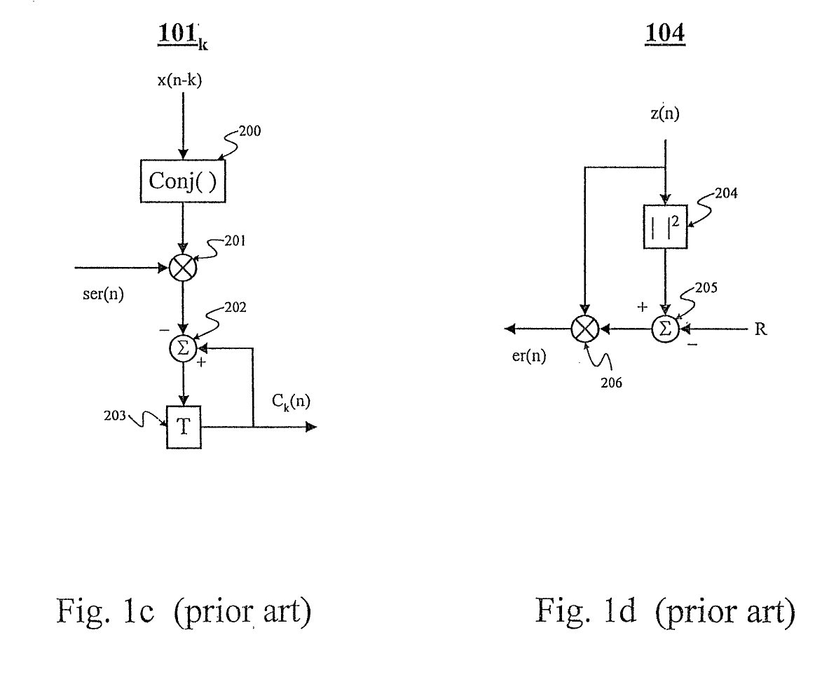

the superscript “*” denotes complex conjugation, R is a number explained below, and f(er(n))=er(n) for the basic technique described below and f(er(n))=sgn(er(n)) for the sign technique described below. (“sgn” denotes the so-called signum function whose value is equal to +1 when its argument is positive or zero and is equal to −1 when its argument is negative.) FIG. 3e shows the details of each coefficient adapter (501ₖ, where k=0,1, . . . ,N−1) in the coefficient estimator part. It is structurally the same as FIG. 1c except for different numeral designations of the components. The coefficient adapter takes x(n−k), which is the k-th delayed sample of the equalizer input, as one input and feeds the sample through a conjugator 650 to obtain its complex conjugate. The conjugator output and ser(n), which is the output of the error scaler 505, are then multiplied together 651. The product is fed into a subtraction operation 652 to adjust the k-th equalizer coefficient Cₖ(n). After a unit-sample delay 653, the adjusted coefficient will become the k-th equalizer coefficient at the next time instant.

FIG. 3f shows the details of the coefficient-effect estimator 517. It is structurally the same as FIG. 2e except for different numeral designations of the components. The coefficient-effect estimator takes the error signal er(n) and passes it through the scaler 700 to scale it by the adaptation step size u. The scaled error signal is fed into a subtraction operation 701 to adjust the coefficient-effect estimate h(n). After a unit-sample delay 702, the adjusted estimate will become the estimate at the next time instant. It is verified via computer simulation that the structure embodied in FIG. 3f is able to estimate the quantity

$${\sum }_{k = 0}^{N / 2 - 1} {C}_{2 k} ( n ) {C}_{2 k + 1} ( n )$$

as desired.

FIG. 3g shows one way of embodying the error scaler 505 which will be referred to as the basic technique. FIG. 3h shows a second way of embodying the error scaler 505, called the sign technique, where the hardlimiter 771 outputs +1 when er(n) is greater than or equal to 0 and outputs −1 when er(n) is less than 0. This hardlimiting reduces the multiplication complexity in the coefficient adapters (501₀, 501₁, . . . ,501_{N-1}) because it reduces ser(n) to have two levels only. If, in addition, the adaptation step size s is an integral power of 2, then the multiplication is reduced to a simple shift of the binary point and can be accomplished without a multiplier in its usual sense.

FIG. 3i shows the details of the blind error calculator 504. It is structurally the same as FIG. 1d. The blind error calculator takes z(n), the output of the convolver at time n, as the input and feeds it through the squared-magnitude calculator 800. A number R is subtracted 801 from the squared magnitude of z(n).

For the basic technique where the error scaler 505 is embodied in the form illustrated in FIG. 3g, R is the ratio of the expected value of the fourth-power values of the magnitudes of the transmitted data symbols from the remote end to the expected value of the squared magnitudes of the transmitted data symbols from the remote end.

For the sign technique where the error scaler 505 is embodied in the form illustrated in FIG. 3h, R may be a different number which can be determined through experiments in the form of computer simulation. More precisely, the sign technique of blind equalization can be programmed for computer simulation, with the number R left as a variable whose value is yet to be determined. The computer simulation is executed for typical communication channel characteristics in which the designed blind equalizer is to operate, under different values of the number R. The value that results in a lower ISI in the equalizer output z(n) may be chosen. In the blind error calculator 504, the resulting difference from the subtraction operation 801 is multiplied 802 with z(n) to form the blind error signal er(n), which gives the calculator's output.

In FIGS. 3a-3i and the associated description above, the number of equalizer coefficients N for the convolver part has been assumed to be even. For an odd N, let N′=N+1 and substitute all appearances of N in FIGS. 3a-3i and the associated description above by N′, then omit all the appearances of C_{N′-1} (n). In particular, the coefficient adapter 501_{N′-1} in FIG. 3a (recall that N′ has now replaced N in the figure), is omitted along with the summation 510_{N′-2}, making the signal line 512_{N′-2} directed connected with the signal line 507_{N′-2}. The result is the structure for odd N.

Similar to the case of Godard p=2 blind equalization, the number of equalizer coefficients N for the convolver part and the adaptation step sizes s and u are design parameters to be chosen at the discretion of the implementer.

In general, the greater the adaptation step sizes s and u are, the faster the equalizer converges, but also the greater the steady-state residual ISI in the equalizer output z(n) becomes. An implementer may also let the adaptation step sizes s and u vary with time. For example, one may determine to have two phases in equalizer operation. In the first phase, greater adaptation step sizes are used to effect a fast convergence, while in the second phase, smaller adaptation step sizes are used to effect a small steady-state residual ISI. The above example is illustrative of the ways the blind equalizer of the present invention may be incorporated in a practical digital communication transmission system.

Other embodiments may be devised by those skilled in the art without departing from the spirit and scope of the present invention. In experiments concerning cable modem transmission conducted via computer simulation, both the adaptation step sizes s and u are found to have a wide range of values in which equalizer convergence is assured, of which the range of the step size u in the coefficient-effect estimator 517 is the greater of the two.

For complexity reason, the step sizes s and u can be chosen to be integral powers of 2 or simple binary numbers to facilitate ease of scaler implementation (505, 700).

In a practical communications receiver, the equalizer output signal z(n) may be fed into a simple decision circuit to determine what the transmitted data from the remote end are, or into a more involved structure (such as a decision-feedback equalizer or a maximum-likelihood sequence estimator) for a more accurate determination.

In summary, a most significant feature of this invention lies in the combined advantages of blind equalization and the decomposition technique for convolver implementation. The structure requires no training sequence and needs only half the number of multiplications for convolution as compared to customary equalization. Theoretically, the technique may be considered as a simplified, practical version of an ideal, unrealizable blind equalizer. This ideal, unrealizable blind equalizer contains infinitely many equalizer coefficients for its convolver part and its adaptation step sizes tend to infinitely small as time approaches infinity. For this ideal blind equalizer, it can be shown that the coefficient adaptation process will converge to the complete elimination of ISI in a noiseless environment, if the initial setting of the equalizer coefficients is properly chosen such that the convergence of the equalized channel response to a complete null is prevented.

The foregoing is considered as illustrative only of the principles of the invention. Further, since numerous modifications and changes will readily occur to those skilled in the art, it is not desired to limit the invention to the exact construction and operation shown and described, and, accordingly, all suitable modifications and equivalents may be resorted to, falling within the scope of the invention.

What is claimed is:

1. A method of blind equalization at low complexity employing a technique, capable of reducing or removing ISI from received signals to derive correct transmitted data without needing the transmitting end of the received signal to send out training sequences, said method comprising the following steps at each sample time:
executing a convolver operation for convolution between equalizer inputs and equalizer coefficients by a decomposition technique which uses the coefficients and a coefficient-effect estimate supplied by a coefficient estimator operation;
executing the coefficient estimator operation for updating of the coefficients and coefficient-effect estimate for use by the convolver operation at the next time instant, which is further comprised of the steps of:
executing a blind error calculator operation for a value based on the current-time output of the convolver operation for use in coefficients adaptation and the coefficient-effect estimation;
executing an error scaler operation for the multiplication of output value of the blind error calculator operation by an adaptation step size;
executing coefficient adapters operation for adjustment of the coefficients based on current and past equalizer inputs and the output of the error scaler operation; and
executing a coefficient-effect estimator operation for adjustment of the coefficient-effect estimate by a scaled value of the output of the blind error calculator operation.

2. The method of blind equalization at low complexity as set forth in claim 1, wherein the technique is a sign technique.

3. The method of blind equalization at low complexity as recited in claim 2 wherein said error scaler operation outputs a positive or negative adaptation step size value depending on whether the output value of the blind error calculator is nonnegative or negative.

4. Apparatus for blind equalization at low complexity employing a technique, capable of reducing or removing ISI from the received signals to derive the correct transmitted data without needing the transmitting end to send out training sequences, said apparatus comprising:
convolver means to calculate, at each sample time, the convolution between equalizer input and the equalizer coefficients by the decomposition technique, using coefficients and coefficient-effect estimate supplied by a coefficient estimator; and
coefficient estimator means to provide the convolver, at each sample time, with current-time coefficients and the coefficient-effect estimate and to update the coefficients and the coefficient-effect estimate for use by the convolver at the next time instant, which is further comprised of:
blind error calculator means which calculates a value based on the current-time output of the convolver for the use in coefficients adaptation and the coefficient-effect estimation;
error scaler means which multiplies the output value of the blind error calculator by an adaptation step size;
coefficient adapters means which adjusts the coefficients based on current and past equalizer inputs and the output of the error scaler; and
coefficient-effect estimator means which adjusts the coefficient-effect estimate by a scaled value of the blind error calculator output.

5. The apparatus for blind equalization as set forth in claim 4, wherein the technique is a sign technique.

6. The apparatus for blind equalization as set forth in claim 5, wherein said error scaler means outputs a positive or negative adaptation step size value depending on whether the output value of the blind error calculator is nonnegative or negative.
